(19) United States
(12) Patent Application Publication
(10) Pub. No.: US 2023/0386934 A1
(43) Pub. Date: Nov. 30, 2023

(54) METHODS AND SYSTEMS FOR FORMING DIPOLE LAYERS IN STACKED GATE-ALL-AROUND TRANSISTORS

(71) Applicant: ASM IP Holding, B.V., Almere (NL)

(72) Inventors: Shaoren Deng, Ghent (BE); Marko Tuominen, Helsinki (FI); Vincent Vandalon, Heverlee (BE); Eva E. Tois, Espoo (FI); Viraj Madhiwala, Heverlee (BE); YongGyu Han, Leuven (BE); Daniele Chiappe, Munich (DE); Michael Givens, Oud-Heverlee (BE); Ren-Jie Chang, Leuven (BE); Giuseppe Alessio Verni, Vantaa (FI); Timothee Blanquart, Oud-Heverlee (BE); René Henricus Jozef Vervuurt, Leuven (BE)

(21) Appl. No.: 18/322,286

(22) Filed: May 23, 2023

Related U.S. Application Data
(60) Provisional application No. 63/345,315, filed on May 24, 2022.

(51) Int. Cl. H01L 21/8238

(52) U.S. Cl. CPC H01L 21/823807

(57) ABSTRACT

Disclosed are methods and related systems for forming a structure. Embodiments of presently described methods comprise employing a sacrificial gap filling fluid for selectively forming a first layer on one or more first surfaces in a lower part of a gap, and forming a second layer on one or more second surfaces in an upper part of a gap.

### FIELD OF INVENTION

The present disclosure generally relates to the field of semiconductor processing methods and systems, and to the field integrated circuit manufacture. In particular, methods and systems suitable for forming dipole layers are disclosed.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge relates to creating stacked transistors having different threshold voltages, for example for complementary field effect transistors comprising a first MOSFET and a second MOSFET stacked on each other, the first MOSFET and the second MOSFET each being independently selected from a p-channel MOSFET and an n-channel MOSFET.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Described herein is an embodiment of a method of forming a structure. The method comprises a step of providing a substrate. The substrate comprises a gap. The gap comprises a lower part and an upper part. The method further comprises forming a first layer on one or more first surfaces in the lower part of the gap and on one or more second surfaces in the upper part of the gap. The method further comprises forming a gap filling fluid in the lower part of the gap. The method further comprises selectively etching the first layer with respect to the gap filling fluid. Thus, the first layer is removed from the one or more second surfaces in the upper part of the gap. The method further comprises forming a second layer on the one or more second surfaces in the upper part of the gap. The first layer and the second layer have a different composition. Then, the method comprises a step of removing the gap filling fluid.

Further described herein is another embodiment of a method of forming a structure. The method comprises providing a substrate. The substrate comprises a gap. The gap comprises a lower part and an upper part. The lower part comprises a first set of nanosheets. The upper part comprises a second set of nanosheets. The method further comprises forming a first layer on the first set of nanosheets and on the second set of nanosheets. The method further comprises forming a gap filling fluid in the lower part of the gap. Thus, the first set of nanosheets are encapsulated in gap filling fluid. The method further comprises selectively etching the first layer with respect to the gap filling fluid. Thus, the first layer is removed from the second set of nanosheets. The method further comprises forming a second layer on the second set of nanosheets. It shall be understood that the first layer and the second layer have a different composition. The method further comprises removing the gap filling fluid.

In some embodiments, the step of removing the gap filling fluid from the lower part of the gap is followed by forming a high-k dielectric on the first layer and on the second layer. Then, the substrate can be annealed. Thus, a first gate dielectric is formed from the first layer and the high-k dielectric and a second gate dielectric is formed from the second layer and the high-k dielectric.

Further described herein is another embodiment of a method of forming a structure. The method comprises providing a substrate. The substrate comprises a gap. The gap comprises a lower part and an upper part. The lower part comprises a first set of nanosheets. The upper part comprises a second set of nanosheets. The method further comprises forming a high-k dielectric on the first set of nanosheets and on the second set of nanosheets. The method further comprises forming a first layer on the high-k dielectric on the first set of nanosheets and on the high-k dielectric on the second set of nanosheets. The method further comprises forming a gap filling fluid in the lower part of the gap. Thus, the first set of nanosheets is encapsulated in gap filling fluid. The method further comprises selectively etching the first layer with respect to the gap filling fluid and with respect to the high-k dielectric. Thus, the first layer is removed from the second set of nanosheets. The method further comprises forming a second layer on the high-k dielectric on the second set of nanosheets. The first layer and the second layer have a different composition. The method further comprises a step of removing the gap filling fluid.

In some embodiments, at least one of the first set of nanosheets and the second set of nanosheets comprise a monocrystalline semiconductor.

In some embodiments, the step of removing the gap filling fluid is followed by a step of annealing the substrate. Thus, a first gate dielectric is formed from the first layer and the high k-dielectric. Also, a second gate dielectric is formed from the second layer and the high-k dielectric.

In some embodiments, the gap filling fluid comprises an oligomeric compound.

In some embodiments, the gap filling fluid comprises a plurality of imide functional groups.

In some embodiments, forming the gap filling fluid comprises exposing the substrate to a gap fill precursor and exposing the substrate to a gap fill reactant.

In some embodiments, forming the gap filling fluid comprises executing a cyclical gap fill deposition process. The cyclical gap fill deposition process comprises a plurality of gap fill deposition cycles, ones from the gap fill deposition cycles comprising a gap fill precursor pulse and a gap fill reactant pulse. The gap fill precursor pulse comprises exposing the substrate to a gap fill precursor. The gap fill reactant pulse comprises exposing the substrate to a gap fill reactant.

In some embodiments, forming the gap filling fluid comprises generating a plasma.

In some embodiments, forming the gap filling fluid is done thermally.

In some embodiments, forming the first layer comprises executing a cyclical first layer deposition process. The cyclical first layer deposition process comprises a plurality of first layer deposition cycles. A first layer deposition cycle comprises a first cycle precursor pulse and a first cycle reactant pulse. The first cycle precursor pulse comprises exposing the substrate to a first cycle precursor. The first cycle reactant pulse comprises exposing the substrate to a first cycle reactant.

In some embodiments, forming the second layer comprises executing a cyclical second layer deposition process. The cyclical second layer deposition process comprises a plurality of second layer deposition cycles. A second layer deposition cycle comprises a second cycle precursor pulse and a second cycle reactant pulse. The second cycle precursor pulse comprises exposing the substrate to a second cycle precursor. The second cycle reactant pulse comprises exposing the substrate to a second cycle reactant.

In some embodiments, at least one of the first cycle reactant and the second cycle reactant comprises an oxygen reactant. The oxygen reactant is selected from O₂, O₃, H₂O, H₂O₂, N₂O, NO, NO₂, and NO₃.

In some embodiments, at least one of the first cycle precursor and the second cycle precursor comprises a rare earth element.

In some embodiments, at least one of the first cycle precursor and the second cycle precursor comprises a post transition metal.

In some embodiments, the gap fill precursor comprises two or more anhydride functional groups.

In some embodiments, the gap fill reactant comprises two or more amine functional groups.

In some embodiments, at least one of the first cycle precursor and the second cycle precursor comprises a halogen.

In some embodiments, at least one of the first cycle precursor and the second cycle precursor comprises a carbon-containing ligand.

Further described herein is a substrate processing system. The substrate processing system comprises a gap fill reaction chamber, a gap fill etching chamber, a layer reaction chamber, a layer etching chamber, and a wafer transfer robot. The wafer transfer robot is arranged for moving a wafer between the gap fill reaction chamber, the gap fill etching chamber, the layer reaction chamber, and the layer etching chamber, without any intervening vacuum break. The gap fill reaction chamber is arranged for forming a gap filling fluid on the wafer. The gap fill etching chamber is arranged for removing the gap filling fluid from the wafer. The layer reaction chamber is arranged for forming a first layer and a second layer on the wafer. The gap fill etching chamber is arranged for at least partially removing at least one of the first layer and the second layer from the wafer.

In some embodiments, the substrate processing system further comprises a controller that is arranged for causing the substrate processing system to carry out a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIGS. 1a-1j show an embodiment of a process for forming two distinct gate dielectrics for the nMOS and pMOS parts of a complimentary field effect transistor (cFET).

FIGS. 2a-2i show another embodiment of a process for forming two distinct gate dielectrics for the nMOS and pMOS parts of a complimentary field effect transistor (cFET).

FIG. 3 schematically shows a flow chart of an embodiment of a method as described herein.

FIG. 4 schematically shows an embodiment of a structure (400) that can be formed using a method as described herein.

FIG. 5 shows another embodiment of a structure (500) that can be formed by way of an embodiment of a method as disclosed herein.

FIGS. 6a-6c show further embodiments of structures (600) that can be formed by way of an embodiment of a method as disclosed herein.

FIG. 7 shows an embodiment of a substrate processing system (700).

FIG. 8 illustrates another embodiment of a structure (800) in accordance with an embodiment of the present disclosure.

FIG. 9 illustrates a system (900) in accordance with yet additional exemplary embodiments of the disclosure.

FIG. 10 shows an embodiment of a precursor pulse.

FIG. 11 shows an embodiment of a cyclical deposition process.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures, gate dielectric structures. Exemplary methods can be used to, for example, to form complementary field effect transistors or portions of such devices. This notwithstanding, and unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as gaps, protrusions, and the like formed within or on at least a portion of a layer of the substrate. By way of examples, a substrate can include bulk semiconductor material and an insulating or dielectric material layer overlying at least a portion of the bulk semiconductor material. Additionally or alternatively, an exemplary substrate can comprise bulk semiconductor material and a conductive layer overlying at least a portion of the bulk semiconductor material. Suitable substrate supports include pedestals, susceptors, and the like.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices.

As used herein, a “structure” can be or include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g., using an inert gas, such as a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used, e.g., in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein. The terms “precursor” and “reactant” can be used interchangeably.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

In this disclosure, any defined meanings do not necessarily exclude ordinary and customary meanings, in some embodiments.

Described herein is a method of forming a structure. The method comprises a step of providing a substrate. The substrate comprises a gap, such as a gap. A gap in a substrate may refer to a patterned recess, hole, via, trench, or depression in that substrate. In some embodiments, the substrate can comprise a plurality of adjacent gaps that may be interconnected. In some embodiments, the gap has sidewalls. Additionally or alternatively, the gap can comprise empty space and one or more nanosheets. In some embodiments, the gap can be positioned between adjacent surface features, such as structures. The gap further comprises a lower part and an upper part. Thus, in some embodiments, the sidewalls of the gap also have corresponding lower parts and upper parts.

In some embodiments, a method as described herein further comprises a step of forming a first layer on the sidewalls in the lower part of the gap and on the sidewalls in the upper part of the gap.

In some embodiments, a method as described herein further comprises forming a gap filling fluid in the lower part of the gap. This can be done, for example by forming a relatively limited amount of gap filling fluid that only partially fills the gap, e.g., that only fills the gap about half-way. Alternatively, the gap can be fully filled with gap filling fluid which is then partially removed such that gap filling fluid remains in only a lower part of the gap.

In some embodiments, the lower gap extends throughout the lower 30% to 70% of the gap, or throughout the lower 40% to 60% of the gap.

The method further comprises a step of selectively etching the first layer with respect to the gap filling fluid. Thus, the first layer is removed in the upper part of the gap. It shall be understood that the first layer remains present in the lower part of the gap since at that location, it is protected from the etchant by the gap filling fluid.

The method further comprises a step of forming a second layer on one or more surfaces in the upper part of the gap. It shall be understood that the first layer and the second layer have a different composition. In some embodiments, the second layer is selectively formed on those second surfaces vis-à-vis the gap filling fluid. This can advantageously facilitate removal of the gap filling fluid in a further process step.

The method further comprises a step of removing the gap filling fluid. Suitable ways of removing gap filling fluids are disclosed elsewhere herein.

A method as described herein can be performed using a substrate that comprises a gap that in turn comprises one or more nanosheets. It shall be understood that the term “nanosheet” as used herein includes the meaning of other elongate features, such as nanowires, nanorods, and nanotubes. In some embodiments, a nanosheet has a critical dimension of at least 1 nm to at most 50 nm, or of at least 1 nm to at most 5 nm, or of at least 5 nm to at most 20 nm, or of at least 20 nm to at most 50 nm. Thus, further described herein is a method of forming a structure. The method comprises providing a substrate. The substrate comprises a gap. The gap comprises a lower part and an upper part. The lower part comprises a first set of nanosheets. The upper part comprises a second set of nanosheets.

The method further comprises forming a first layer on the first set of nanosheets and on the second set of nanosheets. In some embodiments, the gap has sidewalls. In some embodiments, the first layer is also formed on the sidewalls of the gap.

The method further comprises forming a gap filling fluid in the lower part of the gap, thereby encapsulating the first set of nanosheets in gap filling fluid. This can be done, for example by forming a relatively limited amount of gap filling fluid that only partially fills the gap, e.g., that only fills the gap about half-way. Alternatively, the gap can be fully filled with gap filling fluid which is then partially removed such that gap filling fluid remains in only a lower part of the gap. In any case, it shall be understood that at completion of this process step, the gap filling fluid encapsulates the first set of nanosheets while not encapsulating the second set of nanosheets. Further, it shall be understood that the expression “forming a gap filling fluid” can alternatively be described as a “fluidic deposition”. Optionally, forming the gap filling fluid can be followed by a step of annealing the substrate using a gap filling fluid anneal, for example in a nitrogen or noble gas containing atmosphere. Suitable annealing temperatures can include the range of at least 100° C. to at most 500° C.

The method further comprises selectively etching the first layer with respect to the gap filling fluid. Thus, the first layer is removed from the second set of nanosheets. It shall be understood that the first layer remains present on the first set of nanosheets since at that location, it is protected from the etchant by the gap filling fluid.

The method further comprises a step of forming a second layer on the second set of nanosheets. It shall be understood that the first layer and the second layer have a different composition.

Once the first layer and the second layer have been formed, the gap filling fluid can be removed. Thus, a structure is formed in which a first layer is formed on the first set of nanosheets and in which a second layer is formed on the second set of nanosheets.

In some embodiments, the step of removing the gap filling fluid from the lower part of the gap is followed by forming a high-k dielectric on the first layer and on the second layer. Then, the substrate can, in some embodiments, be annealed. Thus, a first gate dielectric can be formed from the first layer and the high k dielectric, and a second gate dielectric can be formed from the second layer and the high-k dielectric. It shall be understood that the first gate dielectric and the second gate dielectric are different.

A method as described herein can also be performed using a substrate that comprises a gap that in turn comprises one or more nanosheets, such as nanosheets, nanorods, or nanowires, wherein the nanosheets are covered with a high-k dielectric before forming the first or second layer on them. Thus, further described is a method for forming a structure. The method comprises providing a substrate. The substrate comprises a gap. In some embodiments, the gap comprises sidewalls. The gap comprises a lower part and an upper part. The lower part comprises a first set of nanosheets. The second part comprises a second part of nanosheets. The method further comprises forming a high-k dielectric on the first set of nanosheets and on the second set of nanosheets. The method further comprises forming a first layer on the high-k dielectric on the first set of nanosheets and on the high-k dielectric on the second set of nanosheets.

The method further comprises forming a gap filling fluid in the lower part of the gap, thereby encapsulating the first set of nanosheets in gap filling fluid. This can be done, for example by forming a relatively limited amount of gap filling fluid that only partially fills the gap, e.g., that only fills the gap about half-way. Alternatively, the gap can be fully filled with gap filling fluid which is then partially removed such that gap filling fluid remains in only a lower part of the gap. In any case, it shall be understood that at completion of this process step, the gap filling fluid encapsulates the first set of nanosheets while not encapsulating the second set of nanosheets.

The method further comprises selectively etching the first layer with respect to the gap filling fluid, and with respect to the high-k dielectric. Thus, the first layer is removed from the second set of nanosheets. It shall be understood that the first layer remains present on the first set of nanosheets since at that location, it is protected from the etchant by the gap filling fluid.

The method further comprises a step of forming a second layer on the high-k dielectric on the second set of nanosheets. It shall be understood that the first layer and the second layer have a different composition.

Once the first layer and the second layer have been formed, the gap filling fluid can be removed. Thus, a structure is formed in which a first layer is formed on the first set of nanosheets and in which a second layer is formed on the second set of nanosheets.

Then, the substrate can, in some embodiments, be annealed. Thus, a first gate dielectric can be formed from the first layer and the high k dielectric, and a second gate dielectric can be formed from the second layer and the high-k dielectric. It shall be understood that the first gate dielectric and the second gate dielectric are different.

In some embodiments, at least one of the first set of nanosheets and the second set of nanosheets comprise a monocrystalline semiconductor. Suitable monocrystalline semiconductors include doped or undoped silicon. Undoped silicon can be referred to as intrinsic silicon. Doped silicon can include an n-type dopant, such as phosphorous, arsenic, or antimony. Additionally or alternatively, doped silicon can include a p-type dopant, such as boron, aluminum, or indium. In some embodiments, the monocrystalline semiconductor comprises silicon and a group 14 element, such as carbon, germanium, or tin.

In some embodiments, the step of removing the gap filling fluid is followed by a step of annealing the substrate. Suitable anneals comprise subjecting the substrate to thermal energy. For example, an anneal can comprise heating the substrate to at temperature of at least 300° C. to at most 600° C. in an atmosphere comprising N₂. Thus, a first gate dielectric is formed from the first layer and the high k-dielectric. Also, a second gate dielectric is formed from the second layer and the high-k dielectric.

In some embodiments, the gap filling fluid comprises an oligomeric compound. For example, an oligomeric compound can comprise from at least 2 to at most 100 repeating groups, for example 5, 10, 20, or 50 repeating groups.

Suitable gap filling fluids include carbon-containing polymers, such as polyimides, polyvinyl toluene, polyethylene, polypropylene, polyaramids, polyimides, polystyrene, polyamic acids, and polymethyl methacrylate. In some embodiments, the gap filling fluid comprises a plurality of imide functional groups.

In some embodiments, the gap filling fluid can be deposited using a method and apparatus as described in United States patent no. U.S. Ser. No. 10/695,79482.

In some embodiments, forming the gap filling fluid comprises exposing the substrate to a gap fill precursor and exposing the substrate to a gap fill reactant. In some embodiments, the substrate is simultaneously exposed to the gap fill precursor and the gap fill reactant.

In some embodiments, forming the gap filling fluid comprises executing a cyclical gap fill deposition process. The cyclical deposition process comprises a plurality of gap fill deposition cycles. Single gap fill deposition cycles comprise a gap fill precursor pulse and a gap fill reactant pulse. The gap fill precursor pulse comprises exposing the substrate to a gap fill precursor. The gap fill reactant pulse comprises exposing the substrate to a gap fill reactant.

In some embodiment, forming the gap filling fluid comprises generating a plasma. The plasma can be generated in the reaction chamber or in a separate plasma chamber, i.e., a remote plasma unit, that is operationally connected to the reaction chamber in which the gap filling fluid is formed.

In some embodiments, forming the gap filling fluid is done thermally. For example, a polyimide gap filling fluid can be formed thermally.

In some embodiments, forming the first layer, forming the second layer, and forming the gap filling fluid are all done in absence of a plasma. In other words, forming the first layer, forming the second layer, and forming the gap filling fluid is done thermally, in some embodiments. In other words, and in some embodiments, the methods described herein do not include use of a plasma to form activated species for use in a deposition process.

In some embodiments, forming the first layer comprises executing a cyclical first layer deposition process. The cyclical first layer deposition process comprises a plurality of first layer deposition cycles. Individual first layer deposition cycles comprise a first cycle precursor pulse and a first cycle reactant pulse. The first cycle precursor pulse comprises exposing the substrate to a first cycle precursor. The first cycle reactant pulse comprises exposing the substrate to a first cycle reactant.

In some embodiments, forming the second layer comprises executing a cyclical second layer deposition process. The cyclical second layer deposition process comprises a plurality of second layer deposition cycles. Individual second layer deposition cycles comprise a second cycle precursor pulse and a second cycle reactant pulse. The second cycle precursor pulse comprises exposing the substrate to a second cycle precursor. The second cycle reactant pulse comprises exposing the substrate to a second cycle reactant.

In some embodiments, at least one of the first layer and the second layer has a step coverage equal to or greater than about 50%, or greater than about 80%, or greater than about 90%, or about 95%, or about 98%, or about 99% or greater. It shall be understood that the term “step coverage” can refer to the growth rate of a layer on a distal surface of a gap, divided by the growth rate of that layer on a proximal surface of the gap, and expressed as a percentage. It shall be understood that a distal portion of a gap can refer to a portion of the gap which is relatively far removed from a substrate's surface, and that the proximal portion of a gap feature refers to a part of the gap feature which is closer to the substrate's surface compared to the distal/lower/deeper portion of the gap feature.

At least one of a first layer and a second layer having a desired thickness can be formed by executing a suitable number of cycles. The total number of cycles can depend, inter alia, on the total layer thickness that is desired. In some embodiments, at least one of a first layer and a second layer can be formed using from at least 2 cycles to at most 5 cycles, or from at least cycles to at most 10 cycles, or from at least 10 cycles to at most 20 cycles, or from at least 20 cycles to at most 50 cycles, or from at least 50 cycles to at most 100 cycles, or from at least 100 cycles to at most 200 cycles, or from at least 200 cycles to at most 500 cycles, or from at least 500 cycles to at most 1000 cycles, or from at least 1000 cycles to at most 2000 cycles, or from at least 2000 cycles to at most 5000 cycles, or from at least 5000 cycles to at most 10000 cycles.

In some embodiments, at least one of the first layer and the second layer has a thickness from at least 0.1 nm to at most 5 nm, or from at least 0.2 nm to at most 5 nm, or from at least 0.3 nm to at most 4 nm, or from at least 0.4 nm to at most 3 nm, or from at least 0.5 nm to at most 2 nm, or from at least 0.7 nm to at most 1.5 nm or of at least 0.9 nm to at most 1.0 nm.

In some embodiments, at least one of the first layer and the second layer has a thickness of at most 5.0 nm, or a thickness of at most 4.0 nm, or a thickness of at most 3.0 nm, or a thickness of at most 2.0 nm, or a thickness of at most 1.5 nm, or a thickness of at most 1.0 nm, or a thickness of at most 0.8 nm, or a thickness of at most 0.6 nm, or a thickness of at most 0.5 nm, or a thickness of at most 0.4 nm, or a thickness of at most 0.3 nm, or a thickness of at most 0.2 nm, or a thickness of at most 0.1 nm.

It shall be understood that in some embodiments of any cyclic process as described herein, one or more subsequent pulses can be separated by a purge step. Providing purge steps between subsequent pulses can allow minimizing parasitic gas-phase reactions between precursors and reactants.

In some embodiments, at least one of the first cycle reactant and the second cycle reactant comprises an oxygen reactant. The oxygen reactant is selected from O₂, O₃, H₂O, H₂O₂, N₂O, NO, NO₂, and NO₃.

In some embodiments, at least one of the first cycle precursor and the second cycle precursor comprises a rare earth element. Suitable rare earth elements include lanthanum, cerium, praesodynium.

In some embodiments, at least one of the first cycle precursor and the second cycle precursor comprises a d block element. Suitable d block elements include scandium.

In some embodiments, at least one of the first cycle precursor and the second cycle precursor comprises a post transition metal, such as aluminum.

In some embodiments, at least one of the first cycle precursor and the second cycle precursor comprises a halogen, such as chlorine, bromine, or iodine.

In some embodiments, at least one of the first cycle precursor and the second cycle precursor comprises a carbon-containing ligand.

In some embodiments, the gap fill precursor comprises two or more anhydride functional groups. Suitable gap fill precursors include 1,2,4,5-Benzenetetracarboxylic anhydride.

In some embodiments, the gap fill reactant comprises two or more amine functional groups. Suitable gap fill reactants include ethylenediamine, 1,6-diaminohexane, 1,4-phenylenediamine, and 4,4′-oxydianiline.

Further described herein is a processing system. The substrate processing system comprises a gap fill reaction chamber, a gap fill etching chamber, a layer reaction chamber, a layer etching chamber, and a wafer transfer robot. The wafer transfer robot is arranged for moving a wafer between the gap fill reaction chamber, the gap fill etching chamber, the layer reaction chamber, and the layer etching chamber, without any intervening vacuum break. The gap fill reaction chamber is arranged for forming a gap filling fluid on the wafer. The gap fill etching chamber is arranged for removing the gap filling fluid from the wafer. The layer reaction chamber is arranged for forming a first layer and a second layer on the wafer. The gap fill etching chamber is arranged for removing at least one of the first layer and the second layer from the wafer.

In some embodiments, the processing system further comprises a controller. The controller is arranged for causing the substrate processing system to carry out a method as described herein.

A flowable material as used herein can have a low wet etch rate vis-à-vis acidic etchants, such as aqueous hydrogen fluoride (HF) and aqueous hydrogen chloride (HCl) and basic etchants, such as ammonia solution, i.e., NH₃ (aq). Such acidic etchants can be advantageously used for etching at least one of high-k dielectrics, first layers, and second layers. For example, table 1 shows wet etch rate data for a flowable polyimide material.

The flowable material was formed using a cyclical deposition process comprising a plurality of gap fill deposition cycles. A gap fill deposition cycle comprises a gap fill precursor pulse and a gap fill reactant pulse. A gap fill precursor pulse comprises exposing the substrate to a gap fill precursor. A gap fill reactant pulse comprises exposing the substrate to a gap fill reactant.

In exemplary embodiment, the gap fill precursor comprises 1,2,4,5-Benzenetetracarboxylic anhydride (PMDA) and the gap fill reactant comprises 1,6-diaminohexane (DAH). Such a precursor-reactant pair can be employed for cyclically forming a polyimide gap filling fluid using a substrate temperature of at least 150° C. to at most 200° C. and a reaction chamber pressure of at least 0.1 Torr to at most 50 Torr. Suitable PMDA pulse times include from at least 100 ms to at most 20000 ms. Suitable DAH pulse times include from at least 50 ms to at most 10000 ms. A PMDA pulse can be followed by a PMDA purge that can last, for example, from at least 1000 to at most 30000 ms. A DAH pulse can be followed by a DAH purge that can last, for example, from at least 1000 to at most 20000 ms.

Of course, other suitable gap fill precursors or reactants could be used. For example, 1,4-phenylenediamine could be used as a gap fill reactant instead.

A flowable polyimide material can have excellent etch resistance against diluted aqueous HCl and against diluted aqueous HF. Such etchants can etch dipole materials and high-k dielectrics, such as metal oxides. Accordingly, such etchants can be used for selectively etching at least one of a dipole material and a high-k dielectric vis-à-vis a polyimide gap filling fluid.

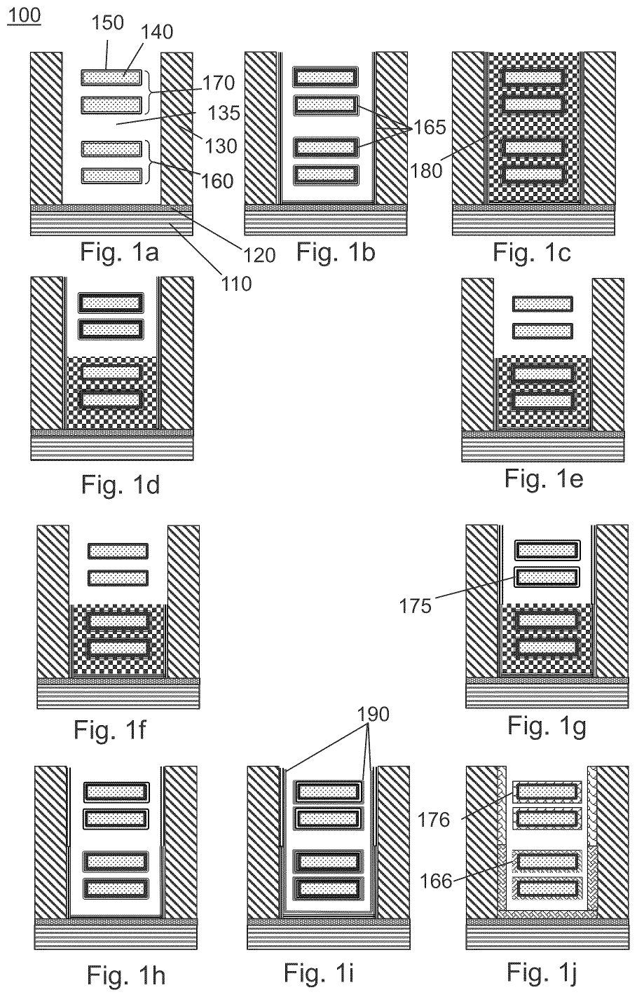

In an exemplary embodiment, reference is made to FIGS. 1a-1J. FIGS. 1a-1j show an embodiment of a process for forming two distinct gate dielectrics for the nMOS and pMOS parts of a complimentary field effect transistor (cFET). In this embodiment, two different dipole layers are formed on an interlayer (150), then a high-k dielectric is formed overlying the two different dipole layers. A structure (100) is particularly shown in FIGS. 1a-1j in various stages of processing.

In particular, FIG. 1a shows the structure (100) that comprises a substrate (110). A dielectric substrate surface layer (120), such as a silicon oxide layer, is formed on the substrate. The structure (100) further comprises spacers (130). The spacers (130) can be made, for example, from a dielectric layer, such as silicon nitride. A gap (135) is present between the spacers (130). Two sets of nanosheets (160,170) are located in the gap: a first set of nanosheets (160) and a second set of nanosheets (170). At least one of the first set of nanosheets (160) and the second set of nanosheets (170) can, in some embodiments, comprise silicon. Each of the sets (160,170) comprises at least one nanosheet (140), and the surface of each nanosheet (140) comprises an interlayer (150). In the embodiment shown, each of the sets (160,170) comprises two nanosheets (140). This notwithstanding, configurations with three or more nanosheets per set are possible as well. It shall be understood that other nanosheets apart from nanosheets can be used as well. Examples of suitable nanosheets include nanorods, nanowires, and nanotubes.

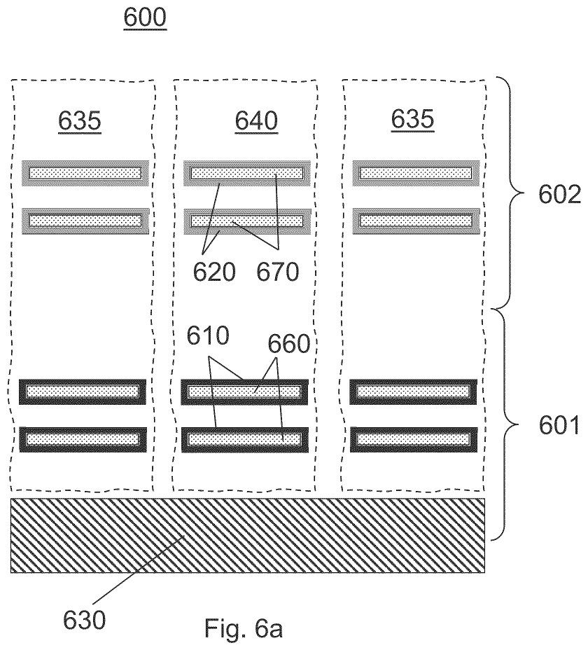

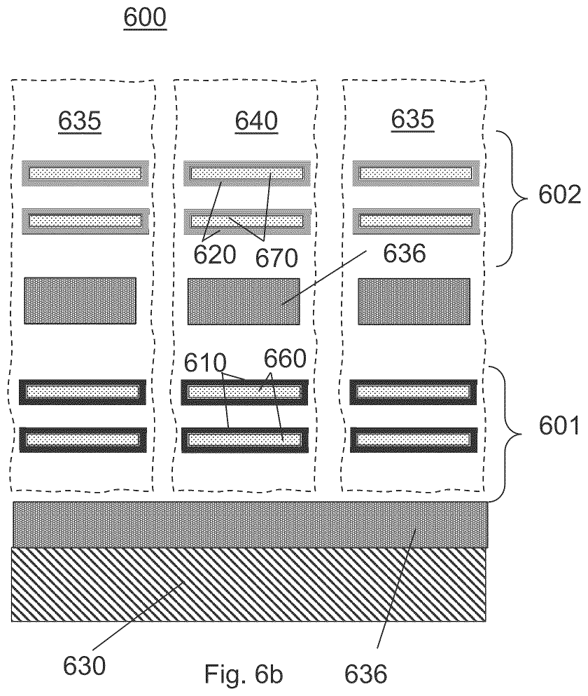

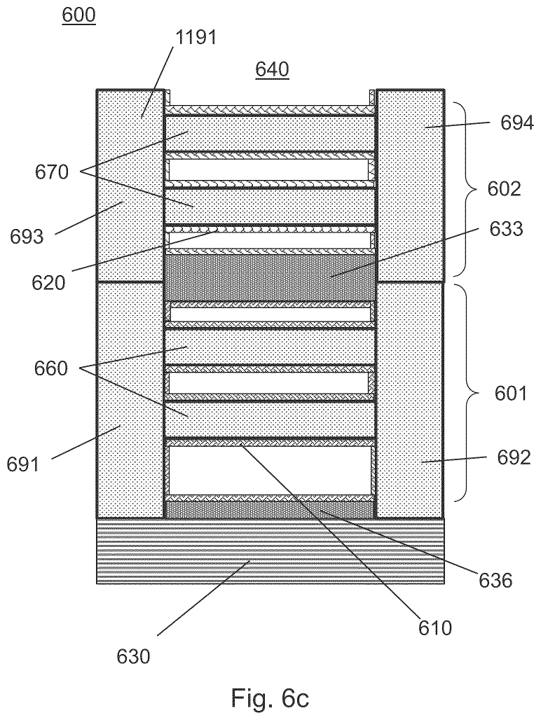

FIG. 1b shows the structure (100) after a first dipole layer (165) formed using a conformal deposition technique. Suitable conformal deposition techniques include cyclical deposition techniques, such as atomic layer deposition (ALD). The first dipole layer (165) is formed on the first set of nanosheets (160) and on the second set of nanosheets (170). In addition, the first dipole layer (165) is also formed on the dielectric substrate surface layer (120) and on the spacers (130). It shall be understood that the spacers (130) are not necessarily monolithic, and can even be omitted, in some embodiments. For example, the gap (135) can correspond to an empty space between two adjacent structures, as is for example shown in FIGS. 6a and 6b.

FIG. 1c shows the structure (100) after the gap (135) has been filled with a gap filling fluid (180). Suitable gap filling fluids include carbon-containing oligomers. Suitable carbon-containing oligomers include oligomeric hydrocarbons, oligomeric amides, oligomeric amines, oligomeric polyurethanes, and oligomeric imides. The gap filling fluid covers both the first set of nanosheets (160) and the second set of nanosheets (170).

FIG. 1d shows the structure (100) after the gap filling fluid (180) has been partially etched away to uncover the second set of nanosheets (170) while still covering the first set of nanosheets (160). In some embodiments, the gap filling fluid (180) can be etched using exposure to an oxygen-containing gas, such as O₂, H₂O₂, H₂O, O₃, N₂O, NO, or NO₂. Alternatively, the gap filling fluid (180) can be etched using a plasma employing a plasma gas comprising one or more of H₂, N₂, and NH₃. Thus, in some embodiments, the etch process may comprise exposing the substrate to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof . . . In some embodiments, the plasma may also comprise noble gas species, for example Ar or He species. In some embodiments the plasma may consist essentially of noble gas species. In some instances, the plasma may comprise other species, for example nitrogen atoms, nitrogen radicals, nitrogen plasma, or combinations thereof.

Alternatively, the gap filling fluid can be removed using a wet etchant solution, such as a wet etchant solution a polar solvent or an alkaline solution. Suitable solvents can include dipolar amides, such as N-Methyl-2-Pyrrolidone, dimethylacetamide, and dimethylformamide. Further suitable solvents can include alkyl sulfoxides, such as dimethyl sulfoxide, phenol derivatives, such as m-cresol and ortho-chlorophenol, and chlorinated solvents, such as chloroform.

In alternative embodiments, the etching step can be omitted and the structure of FIG. 1d can be obtained by filling the gap (135) half-way with gap filling fluid (180).

FIG. 1e shows the structure (100) after the first dipole layer (165) has been etched away from the second set of nanosheets (170). The etchant which is used selectively etches the first dipole layer (165) vis-à-vis the gap filling fluid (180). Thus, the first dipole layer on the second set of nanosheets (170) is etched away while the first dipole layer (165) on the first set of nanosheets (160) is protected by the gap filling fluid (180) and is left intact.

In some embodiments, the etchant can damage or influence the gap filling fluid (180) in an undesirable way, e.g., in a way that compromises its growth-inhibiting properties. Thus, in some embodiments, the remaining gap filling fluid can optionally be removed completely, and can the gap (135) can be partially refilled. As before, partial refilling can occur via filling completely and subsequent etching, or by filling the gap (135) half-way. Thus, a structure (100) comprising a refilled gap can be obtained, as is shown in FIG. 1f.

FIG. 1g shows the structure (100) after a second dipole layer (175) has been formed using a conformal deposition technique, such as ALD. It shall be understood that the first and second dipole layers have a different composition. For example, one of the first dipole layer and the second dipole layer can comprise a post transition metal oxide, such as aluminum oxide, and the other can comprise an oxide of a rare earth element, such as lanthanum oxide.

FIG. 1h shows the structure (100) after the gap filling fluid (180) has been fully removed from the structure (100).

FIG. 1i shows the structure (100) after a high-k layer (190) has been formed overlying the first dipole layer (165) and the second dipole layer (175). In some embodiments, the high-k layer can be formed using a conformal deposition method, such as atomic layer deposition (ALD). Suitable high-k layers include hafnium oxide.

FIG. 1j shows the structure (100) in which, after an anneal, a first gate dielectric (166) is formed on the first set of nanosheets (160), and a second gate dielectric (176) is formed on the second set of nanosheets. The first gate dielectric (166) and the second gate dielectric (176) comprise a different dipole. For example, the first gate dielectric (166) comprises a p-type dipole and the second gate dielectric (176) comprises an n-type dipole; or the first gate dielectric (166) comprises an n-type dipole and the second gate dielectric (176) comprises a p-type dipole. A structure (100) as shown in FIG. 1j can be particularly advantageous for forming a complementary field effect transistor comprising a first transistor and a second transistor, the first transistor comprising a first set of nanosheets and a first gate dielectric, the second transistor comprising a second set of nanosheets and a second gate dielectric. Since the first gate dielectric and the second gate dielectric comprise a different dipole, their threshold voltage can be independently controlled.

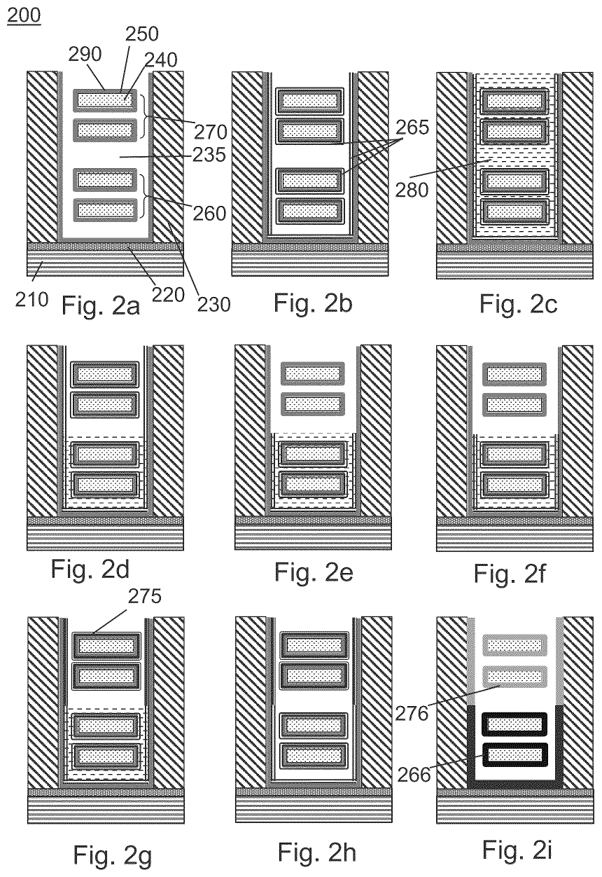

In a further exemplary embodiment, reference is made to FIGS. 2a-2i. FIGS. 2a-2i show another embodiment of a process for forming two distinct gate dielectrics for the nMOS and pMOS parts of a complimentary field effect transistor (cFET). A structure (200) is particularly shown in FIGS. 2a-2i in various stages of processing.

In particular, FIG. 2a shows the structure (200) that comprises a substrate (210). A dielectric substrate surface layer (220), such as a silicon oxide layer, is formed on the substrate. The structure (200) further comprises spacers (230). The spacers (230) can be made, for example, from a dielectric layer, such as silicon nitride. A gap (235) is present between the spacers (230). Two sets of nanosheets (260,270) are located in the gap: a first set of nanosheets (260) and a second set of nanosheets (270). At least one of the first set of nanosheets (260) and the second set of nanosheets (270) can, in some embodiments, comprise silicon. Each of the sets (260,270) comprises at least one nanosheet (240), and the surface of each nanosheet (240) comprises an interlayer (250). In the embodiment shown, each of the sets (260,270) comprises two nanosheets (240). This notwithstanding, configurations with three or more nanosheets per set are possible as well. A high-k material (290) is present on the interlayer (250) of the first set of nanosheets (260) and on that of the second set of nanosheets (270). In addition, the high-k material is also formed on the dielectric substrate surface layer (220) and on the spacers (230).

FIG. 2b shows the structure (200) after a first dipole layer (265) formed using a conformal deposition technique. Suitable conformal deposition techniques include cyclical deposition techniques, such as atomic layer deposition (ALD). The first dipole layer (265) is formed on the high-k material (290) overlying the first set of nanosheets (260) and on the high-k material overlying the second set of nanosheets (270). In addition, the high-k material is also formed on the first dipole layer (265) overlying the dielectric substrate surface layer (220) and on the first dipole layer (265) overlying the spacers (230).

FIG. 2c shows the structure (200) after the gap (235) has been filled with a gap filling fluid (280). Suitable gap filling fluids are described elsewhere herein and include carbon-containing oligomers. Suitable carbon-containing oligomers include oligomeric hydrocarbons, oligomeric amides, oligomeric amines, oligomeric polyurethanes, and oligomeric imides. The gap filling fluid covers both the first set of nanosheets (260) and the second set of nanosheets (270).

FIG. 2d shows the structure (200) after the gap filling fluid (280) has been partially etched away to uncover the second set of nanosheets (270) while still covering the first set of nanosheets (260). In some embodiments, the gap filling fluid (280) can be etched using exposure to an oxygen-containing gas, such as O₂, H₂O₂, H₂O, or O₃, or N₂O, NO, or NO₂. In some embodiments, the gap filling fluid (280) can be etched using a plasma gas comprising one or more of H₂, N₂, and NH₃. In alternative embodiments, the etching step can be omitted and the structure of FIG. 2d can be obtained by filling the gap (235) half-way with gap filling fluid (280).

FIG. 1e shows the structure (200) after the first dipole layer (265) has been etched away from the second set of nanosheets (270). The etchant which is used selectively etches the first dipole layer (265) vis-à-vis the gap filling fluid (280). Thus, the first dipole layer on the second set of nanosheets (270) is etched away while the first dipole layer (265) on the first set of nanosheets (260) is protected by the gap filling fluid (280) and is left intact.

In some embodiments, the etchant can damage or influence the gap filling fluid (280) in an undesirable way, e.g., in a way that compromises its growth-inhibiting properties. Thus, in some embodiments, the remaining gap filling fluid can optionally be removed completely, and the gap (235) can be partially refilled. As before, partial refilling can occur via filling completely and subsequent gaping, or by filling the gap (235) half-way. Thus, a structure (200) comprising a refilled gap can be obtained, as is shown in FIG. 2f.

FIG. 2g shows the structure (200) after a second dipole layer (275) has been formed using a conformal deposition technique, such as ALD. It shall be understood that the first and second dipole layers have a different composition. For example, one of the first dipole layer and the second dipole layer can comprise a post transition metal oxide, such as aluminum oxide, and the other can comprise an oxide of a rare earth element, such as lanthanum oxide or scandium oxide.

FIG. 2h shows the structure (200) after the gap filling fluid (280) has been fully removed from the structure (200).

FIG. 2i shows the structure (200) in which, after an anneal, a first gate dielectric (266) is formed on the first set of nanosheets (260), and a second gate dielectric (276) is formed on the second set of nanosheets (270). The first gate dielectric (266) and the second gate dielectric (276) comprise a different dipole. For example, the first gate dielectric (266) comprises a p-type dipole and the second gate dielectric (276) comprises an n-type dipole; or the first gate dielectric (266) comprises an n-type dipole and the second gate dielectric (276) comprises a p-type dipole. A structure (200) as shown in FIG. 2i can be particularly advantageous for forming a complementary field effect transistor comprising a first transistor and a second transistor, the first transistor comprising a first set of nanosheets and a first gate dielectric, the second transistor comprising a second set of nanosheets and a second gate dielectric. Since the first gate dielectric and the second gate dielectric comprise a different dipole, their threshold voltage can be independently controlled.

It shall be understood that in some embodiments (not shown), a further layer can be formed prior to the anneal. An example of such a further layer can include a transition metal nitride, such as TiN that can be formed using a conformal deposition technique, such as atomic layer deposition (ALD).

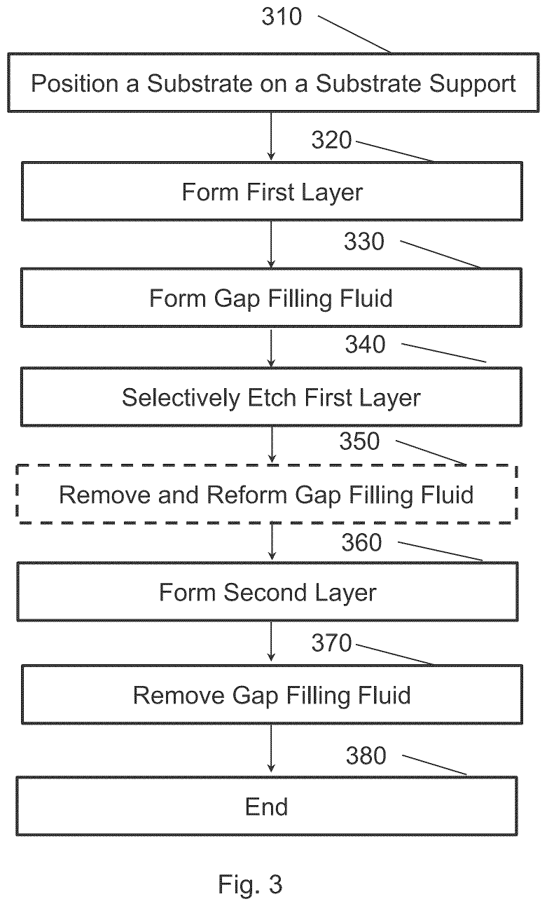

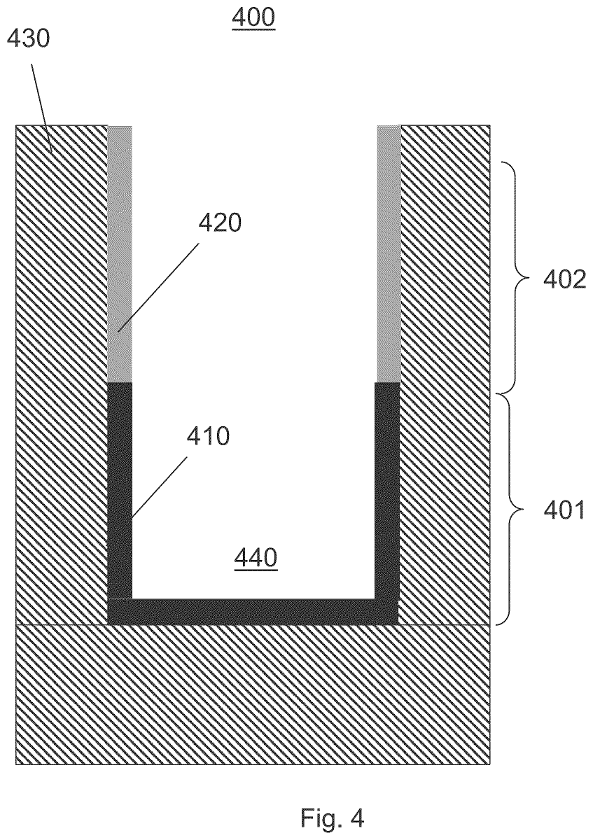

In a further exemplary embodiment, reference is made to FIGS. 3 and 4. FIG. 3 schematically shows a flow chart of an embodiment of a method as described herein. FIG. 4 schematically shows an embodiment of a structure (400) that can be formed using a method as described herein.

A method according to the embodiment shown in FIG. 3 comprises a step (310) of positioning a substrate on a substrate support. The substrate comprises a gap (440) formed in a substrate material (430). The gap (440) comprises a lower part (401) and an upper part (402). In some embodiments (not shown), the gap can comprise further features, such as nanosheets. Indeed, a method according to the embodiment of FIG. 3 can be employed for forming structures as shown in the embodiments of FIGS. 1a-1j and FIGS. 2a-2i.

The method according to the embodiment shown in FIG. 3 further comprises a step (320) of forming a first layer. The first layer can be formed using a conformal deposition technique, and is formed both on the lower part (401) and on the upper part (402) of the gap (440). Suitable conformal deposition techniques include cyclical deposition techniques, such as atomic layer deposition (ALD).

The method according to the embodiment shown in FIG. 3 further comprises a step (330) of forming a gap filling fluid. The gap filling fluid can be formed to fill the lower part (401) of the gap (440), and not the upper part (402) of the gap (440). Alternatively, the gap filling fluid can be formed to fill more than just the lower part (401) of the gap (440), and it can then be partially etched such that, after the etch, it only fills the lower part (401) of the gap (440), and not the upper part (402) of the gap (440). Suitable gap filling fluids are described elsewhere herein and include carbon-containing oligomers.

The method according to the embodiment shown in FIG. 3 further comprises a step (340) of selectively etching the first layer in the upper part (402) of the gap (440) vis-à-vis the gap filling fluid. The gap filling fluid protects the first layer in the lower part (401) of the gap (440). Thus, the first layer in the upper part (402) of the gap is etched away while the first layer in the lower part (401) of the gap (440) is protected by the gap filling fluid and is left intact.

The etching step (340) can, in some embodiments, damage or influence the gap filling fluid in an undesirable way, e.g., in a way that compromises its growth-inhibiting properties. Thus, in some embodiments, the remaining gap filling fluid can optionally be removed completely, and the gap can be partially refilled, which is shown in FIG. 3 as an optional step (350) of removing and reforming the gap filling fluid. As before, partial refilling can occur via filling completely and subsequent gaping, or by filling the gap half-way. Thus, a structure comprising a refilled gap can be obtained.

Then, the method of the embodiment of FIG. 3 comprises a step of forming a second layer (360). The second layer can be formed using a conformal deposition technique, such as ALD. It shall be understood that the first layer and the second layer have a different composition. For example, one of the first layer and the second layer can comprise a post transition metal, such as aluminum oxide, and the other can comprise an oxide of a rare earth element, such as lanthanum oxide. Advantageously, the second layer can be selectively deposited on the upper part (402) of the gap (440) vis-à-vis the gap filling fluid. Thus, the gap filling fluid, not being shielded from process gas by any closed overlying layers formed thereon, can be easily removed in a further processing step (370).

Once the gap filling fluid has been removed, a structure (400) as shown in FIG. 4 is formed. The structure (400) comprises a gap (440) which is formed in a substrate material (430). The gap (440) comprises a lower part (401) and an upper part (402). A first layer (410) is present on the surfaces of the lower part (401) of the gap (440). A second layer (420) is present on the surfaces of the upper part (402) of the gap (440).

In some embodiments, one of the first layer and the second layer comprises a d block metal oxide, such as scandium oxide or a rare earth metal oxide, such as lanthanum oxide. The other of the first layer and the second layer can then comprise a post transition metal oxide, such as gallium oxide or aluminum oxide.

In some embodiments, the high-k material comprises a transition metal oxide, such as hafnium oxide. In some embodiments, hafnium oxide can be deposited using an ALD process using a hafnium precursor and an oxygen reactant. Suitable hafnium precursors include hafnium halides, such as HfCl₄ and alkylamido hafnium precursor, such as Tetrakis(dimethylamido)hafnium (IV). Suitable oxygen reactants include H₂O.

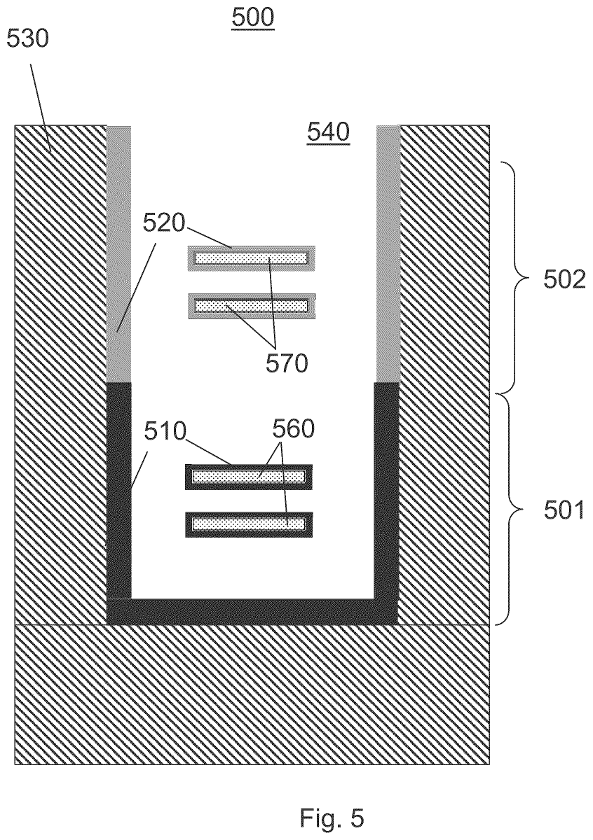

FIG. 5 shows another embodiment of a structure (500) that can be formed by way of an embodiment of a method as disclosed herein. The structure (500) comprises a gap (540) which is formed in a substrate material (530). The gap (540) comprises a lower part (501) and an upper part (502). A first layer (510) is present on the surfaces of the lower part (501) of the gap (540). A second layer (520) is present on the surfaces of the upper part (502) of the gap (540). Two sets of nanosheets (560,570) are located in the gap (540): a first set of nanosheets (560) and a second set of nanosheets (570). In particular, the first set of nanosheets (560) is located in the lower part (501) of the gap (540), and the second set of nanosheets (570) is located in the upper part of the gap (540).

FIG. 6a shows another embodiment of a structure (600) that can be formed by way of an embodiment of a method as disclosed herein. The structure (600) comprises a gap (640) which is formed between adjacent structural features (635). The adjacent structural features (635) can comprise, for example, other structures at the same stage of processing as the structure (600). Indeed, it shall be understood that in integrated circuit manufacture, billions or even trillions of structures (600) can be simultaneously manufactured, and many structures (600) can be positioned side-by-side. The gap (640) overlies a substrate comprising a substrate material (630). The gap (640) comprises a lower part (601) and an upper part (602). A first layer (610) is present on the surfaces of the lower part (601) of the gap (640). A second layer (620) is present on the surfaces of the upper part (602) of the gap (640). Two sets of nanosheets (660,670) are located in the gap (640): a first set of nanosheets (660) and a second set of nanosheets (670). In particular, the first set of nanosheets (660) is located in the lower part (601) of the gap (640), and the second set of nanosheets (670) is located in the upper part of the gap (640). The first layer (610) is formed on the first set of nanosheets (660) and the second layer (620) is formed on the second set of nanosheets (670).

FIG. 6b shows a structure (600) as in FIG. 6a, with the difference that the substrate is covered with a dielectric layer (636), and that a dielectric spacer (637) is positioned between the first set of nanosheets (660) and the second set of nanosheets (670). The dielectric layer (636) and the dielectric spacer (637) can comprise any suitable dielectric, for example silicon oxide, silicon nitride, silicon carbide, and mixtures thereof.

FIG. 6c shows a structure (600) as in FIG. 6c, but in a cross section that is perpendicular on the cross section shown in FIG. 6b. In particular, shown is how the first set of nanosheets (660) bridges a gap (640) between a first source (691) and a first drain (692). Also shown is how the second set of nanosheets (670) bridges a gap (640) between a second source (643) and a second drain (644). Thus, the first set of nanosheets (660) can form the channel region of a first transistor, and the second set of nanosheets (670) can form the channel region of a second transistor (670). In some embodiments, the source (693) of the second transistor can be epitaxially grown on the source (691) of the first transistor. In some embodiments, the drain (694) of the second transistor can be epitaxially grown on the drain (692) of the first transistor.

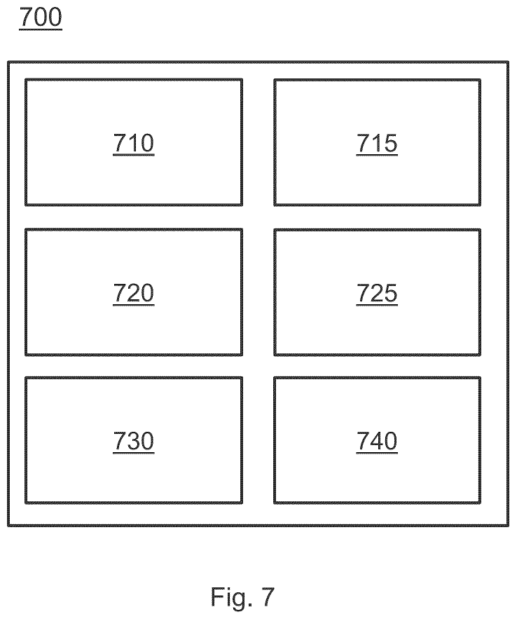

FIG. 7 shows an embodiment of a substrate processing system (700). The substrate processing system (700) comprises a gap fill reaction chamber (710). The gap fill reaction chamber (710) is arranged for forming a gap filling fluid on a substrate. The substrate processing system (700) further comprises a gap fill etching chamber (715). The gap fill etching chamber (715) is arranged for removing the gap filling fluid from the substrate. The substrate processing system (700) further comprises a layer reaction chamber (720). The layer reaction chamber (720) is arranged for forming at least one of a first layer and a second layer on the substrate. The substrate processing system (700) further comprises a layer etching chamber (725). The layer etching chamber (725) is arranged for at least partially removing at least one of the first layer and the second layer from the substrate. The substrate processing system (700) further comprises a wafer transfer robot (730). The wafer transfer robot (730) is arranged for moving a wafer between the gap fill reaction chamber, the gap fill etching chamber, the layer reaction chamber, and the layer etching chamber, without any intervening vacuum break. The substrate processing system (700) further comprises a controller (740). The controller (740) is arranged for causing the substrate processing system to carry out a method as described herein.

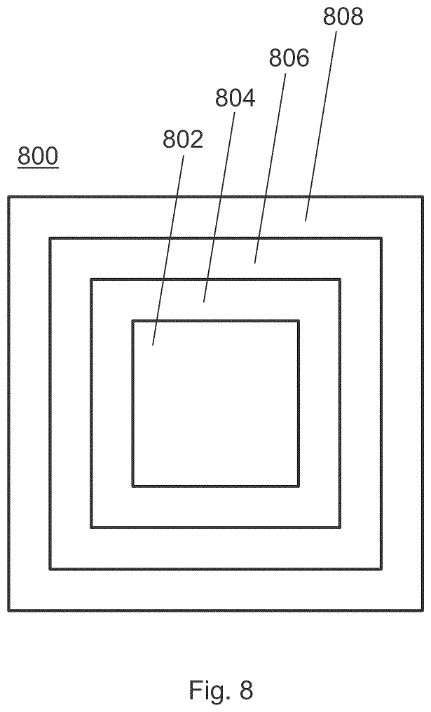

FIG. 8 illustrates another embodiment of a structure (800) in accordance with an embodiment of the present disclosure. This structure (800) is suitable for forming nanosheets comprised in gate all around field effect transistors (GAA FET) (also referred to as lateral nanowire FET) devices and the like, which can in turn be a constituent part of a complimentary field effect transistor.

In the illustrated example, the structure (800) includes semiconductor material (802), dielectric material (804), a work function layer (806), and a conducting layer (808). The structure (800) can be formed overlying a substrate, including any substrate materials described herein. The work function layer (806) can be positioned between the conducting layer (808) and the dielectric material (806), as shown. Alternatively, the work function layer (806) can be positioned inside the conducting layer (808) (embodiment not shown). Suitable work function layers can comprise a metal, a metal carbide, a metal nitride, or a mixture thereof. Suitable metals include transition metals, such as tungsten, molybdenum, ruthenium, post transition metals, such as aluminum, and rare earth metals, such as lanthanum, cerium, and praseodymium. Suitable conducting layers can comprise a metal nitride, such as titanium nitride.

The semiconductor material (802) can include any suitable semiconducting material. For example, the semiconductor material (802) can include Group IV, Group III-V, or Group II-VI semiconductor material. By way of example, the semiconductor material (802) can include silicon.

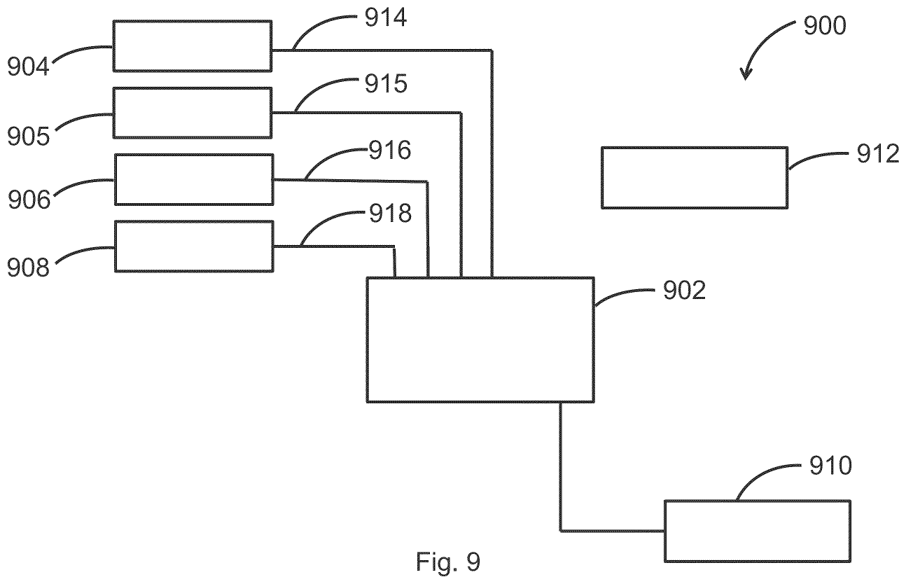

FIG. 9 illustrates a system (900) in accordance with yet additional exemplary embodiments of the disclosure. The system (900) can be used to form a gap filling fluid in a method as described herein and/or form a structure or device portion as described herein.

In the illustrated example, the system (900) includes one or more reaction chambers (902), a gap fill precursor gas source (904), a gap fill reactant gas source (906), a purge gas source (908), an exhaust (910), and a controller (912).

The reaction chamber (902) can include any suitable reaction chamber, such as an ALD or CVD reaction chamber.

The gap fill precursor gas source (904) can include a vessel and one or more precursors as described herein—alone or mixed with one or more carrier (e.g., noble) gases. The gap fill reactant gas source (906) can include a vessel and one or more reactants as described herein—alone or mixed with one or more carrier gases. The purge gas source (908) can include one or more noble gases as described herein. Although illustrated with three gas sources (904)-(908), the system (900) can include any suitable number of gas sources. The gas sources (904)-(908) can be coupled to reaction chamber (902) via lines (914)-(918), which can each include flow controllers, valves, heaters, and the like.

The exhaust (910) can include one or more vacuum pumps.

The controller (912) includes electronic circuitry and software to selectively operate valves, manifolds, heaters, pumps and other components included in the system (900). Such circuitry and components operate to introduce precursors and purge gases from the respective sources (904)-(908). The controller (912) can control timing of gas pulse sequences, temperature of the substrate and/or reaction chamber, pressure within the reaction chamber, and various other operations to provide proper operation of the system (900). The controller (912) can include control software to electrically or pneumatically control valves to control flow of precursors, reactants and purge gases into and out of the reaction chamber (902). The controller (912) can include modules, such as a software or hardware component, e.g., a FPGA or ASIC, which performs certain tasks. A module can advantageously be configured to reside on the addressable storage medium of the control system and be configured to execute one or more processes.

Other configurations of the system (900) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (902). Further, as a schematic representation of a system, many components have been omitted for simplicity of illustration, and such components may include, for example, various valves, manifolds, purifiers, heaters, containers, vents, and/or bypasses.

During operation of the reactor system (900), substrates, such as semiconductor wafers (not illustrated), are transferred from, e.g., a substrate handling system to the reaction chamber (902). Once substrate(s) are transferred to the reaction chamber (902), one or more gases from the gas sources (904)-(908), such as precursors, reactants, carrier gases, and/or purge gases, are introduced into the reaction chamber (902).

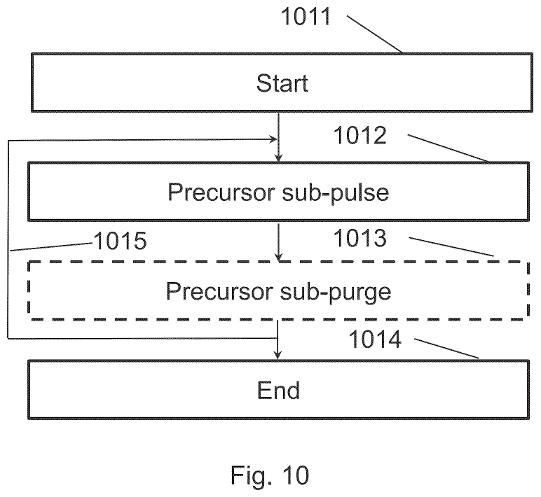

FIG. 10 shows an embodiment of a precursor pulse, e.g., a gap fill precursor pulse, a first precursor pulse, or a second precursor pulse according to an exemplary method as disclosed herein. The precursor pulse starts (1011) and a precursor sub-pulse (1012) is carried out. The precursor sub-pulse is then followed by a precursor sub-purge (1013). The precursor sub-pulse (1012) and the precursor sub-purge (1013) are then repeated (1015) for a pre-determined amount of times, e.g., from at least 1 to at most 10 times, until the precursor pulse ends (1014).

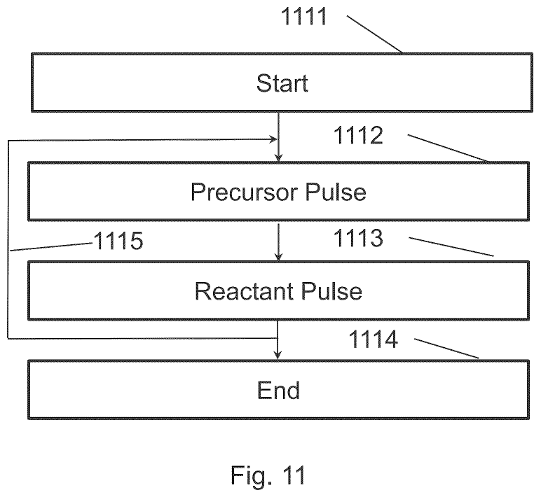

FIG. 11 shows an embodiment of a cyclical deposition process, such as a cyclical deposition process for forming one of a gap filling fluid, a first layer, and a second layer. The method (1100) starts (1111) by providing a substrate. Then, a plurality of deposition cycles (1115) are carried out. A deposition cycle (1115) comprises a precursor pulse (1112) and a reactant pulse (1113). After a pre-determined amount of deposition cycles (1115), the method ends (1114).

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure, comprising
providing a substrate, the substrate comprising a gap, the gap comprising a lower part and an upper part;
forming a first layer on one or more first surfaces in the lower part of the gap and on one or more second surfaces in the upper part of the gap;
forming a gap filling fluid in the lower part of the gap;
selectively etching the first layer with respect to the gap filling fluid, thereby removing the first layer from the one or more second surfaces in the upper part of the gap;
forming a second layer on the one or more second surfaces in the upper part of the gap, the first layer and the second layer having a different composition; and,
removing the gap filling fluid.

2. A method of forming a structure, comprising
providing a substrate, the substrate comprising a gap, the gap comprising a lower part and an upper part, the lower part comprising a first set of nanosheets, the upper part comprising a second set of nanosheets;
forming a first layer on the first set of nanosheets and on the second set of nanosheets;
forming a gap filling fluid in the lower part of the gap, thereby encapsulating the first set of nanosheets in gap filling fluid;
selectively etching the first layer with respect to the gap filling fluid, thereby removing the first layer from the second set of nanosheets;
forming a second layer on the second set of nanosheets, the first layer and the second layer having a different composition; and,
removing the gap filling fluid.

3. The method according to claim 1, wherein the step of removing the gap filling fluid from the lower part of the gap is followed by
forming a high-k dielectric on the first layer and on the second layer; and,
annealing the substrate, thereby forming a first gate dielectric from the first layer and the high k-dielectric; and forming a second gate dielectric from the second layer and the high-k dielectric.

4. A method of forming a structure, comprising
providing a substrate, the substrate comprising a gap, the gap comprising a lower part and an upper part, the lower part comprising a first set of nanosheets, the upper part comprising a second set of nanosheets;
forming a high-k dielectric on the first set of nanosheets and on the second set of nanosheets;
forming a first layer on the high-k dielectric on the first set of nanosheets and on the high-k dielectric on the second set of nanosheets;
forming a gap filling fluid in the lower part of the gap, thereby encapsulating the first set of nanosheets in gap filling fluid;
selectively etching the first layer with respect to the gap filling fluid and with respect to the high-k dielectric, thereby removing the first layer from the second set of nanosheets;
forming a second layer on the high-k dielectric on the second set of nanosheets, the first layer and the second layer having a different composition; and,
removing the gap filling fluid.

5. The method according to claim 2, wherein at least one of the first set of nanosheets and the second set of nanosheets comprise a monocrystalline semiconductor.

6. The method according to claim 4, wherein the step of removing the gap filling fluid is followed by a step of annealing the substrate, thereby forming a first gate dielectric from the first layer and the high k-dielectric; and forming a second gate dielectric from the second layer and the high-k dielectric.

7. The method according to claim 1, wherein the gap filling fluid comprises an oligomeric compound.

8. The method according to claim 1, wherein the gap filling fluid comprises a plurality of imide functional groups.

9. The method according to claim 1, wherein forming the gap filling fluid comprises exposing the substrate to a gap fill precursor and exposing the substrate to a gap fill reactant.

10. The method according to claim 1, wherein forming the gap filling fluid comprises executing a cyclical gap fill deposition process, the cyclical gap fill deposition process comprising a plurality of gap fill deposition cycles, ones from the gap fill deposition cycles comprising a gap fill precursor pulse and a gap fill reactant pulse, wherein the gap fill precursor pulse comprises exposing the substrate to a gap fill precursor, and wherein the gap fill reactant pulse comprises exposing the substrate to a gap fill reactant.

11. The method according to claim 1, wherein forming the gap filling fluid comprises generating a plasma.

12. The method according to claim 1, wherein forming the gap filling fluid is done thermally.

13. The method according to claim 1, wherein forming the first layer comprises executing a cyclical first layer deposition process, the cyclical first layer deposition process comprising a plurality of first layer deposition cycles, ones from the first layer deposition cycles comprising a first cycle precursor pulse and a first cycle reactant pulse, wherein the first cycle precursor pulse comprises exposing the substrate to a first cycle precursor, and wherein the first cycle reactant pulse comprises exposing the substrate to a first cycle reactant.

14. The method according to claim 13, wherein forming the second layer comprises executing a cyclical second layer deposition process, the cyclical second layer deposition process comprising a plurality of second layer deposition cycles, ones from the second layer deposition cycles comprising a second cycle precursor pulse and a second cycle reactant pulse, wherein the second cycle precursor pulse comprises exposing the substrate to a second cycle precursor, and wherein the second cycle reactant pulse comprises exposing the substrate to a second cycle reactant.

15. The method according to claim 14, wherein at least one of the first cycle reactant and the second cycle reactant comprises an oxygen reactant, the oxygen reactant being selected from O₂, O₃, H₂O, H₂O₂, N₂O, NO, NO₂, and NO₃.

16. The method according to claim 14, wherein at least one of the first cycle precursor and the second cycle precursor comprises a rare earth element or a post transition metal.

17. The method according to claim 9, wherein the gap fill precursor comprises two or more anhydride functional groups.

18. The method according to claim 9, wherein the gap fill reactant comprises two or more amine functional groups.

19. The method according to claim 13, wherein at least one of the first cycle precursor and the second cycle precursor comprises a halogen.

20. The method according to claim 13, wherein at least one of the first cycle precursor and the second cycle precursor comprises a carbon-containing ligand.
